(19) United States
(12) Patent Application Publication
(10) Pub. No.: US 2015/0185263 A1
(43) Pub. Date: Jul. 2, 2015

(54) LOCAL OSCILLATOR FREQUENCY CALIBRATION

(71) Applicant: Cambridge Silicon Radio Limited, Cambridge (GB)

(72) Inventors: Timothy Charles Clapp, Sawston (GB); Duncan Angus McLeod, Bar Hill (GB); Michael John Story, Whittlesford (GB)

(73) Assignee: Cambridge Silicon Radio Limited, Cambridge (GB)

(21) Appl. No.: 14/141,021

(22) Filed: Dec. 26, 2013

(51) Int. Cl. G01R 23/02; H03L 7/085; H03L 7/099

(52) U.S. Cl. CPC G01R 23/02; H03L 7/099; H03L 7/085

(57) ABSTRACT

A frequency locked loop for generating a clock signal, comprising: a controllable oscillator configured to, in dependence on a control signal, generate an oscillator signal having an oscillator signal frequency; a frequency divider coupled to the controllable oscillator configured to reduce the oscillator signal frequency to form a divided oscillator signal frequency; and a frequency detector coupled to the frequency divider and configured to generate the control signal in dependence on a reference signal frequency; wherein the frequency divider comprises a first counter and a second counter, the first counter configured to be clocked by the oscillator signal and to produce a first counter output signal, and the second counter configured to be clocked by the first counter output signal.

### BACKGROUND

Frequency locked loops are used on integrated circuit chips to generate an accurate and stable clock signal derived from a reference source of a different frequency.

FIG. 1 illustrates a typical frequency locked loop. Controllable oscillator 101 generates an oscillator signal having an oscillator signal frequency F_{OSC}. Frequency divider 102 divides the oscillator signal frequency down to a value F_{OUT} appropriate for clocking circuitry at the output of the frequency locked loop. Frequency detector 104 compares F_{OUT} to a reference frequency F_{REF} and outputs a signal representative of the ratio of these two frequencies. Loop filter 106 filters the output of the frequency detector. The output of loop filter 106 is a control signal which is input to oscillator 101 to control the frequency F_{OSC} of the oscillator signal generated by the oscillator 101.

It is known to digitally implement the frequency divider, frequency detector and loop filter of a frequency locked loop. This enables greater adaptability to the circuitry at the output of the frequency locked loop than in phased locked loops. For example, the pass band of the loop filter may be narrowed if the reference signal is unstable. Alternatively, the pass band of the loop filter may be widened if it is desirable for the frequency locked loop to adapt the frequency of the oscillator signal quickly to changes in the reference signal. As another example, the frequency detector can be programmed to handle different frequency ratios if F_{REF} changes due to the output circuitry changing or operating in a different mode.

It is known to implement the frequency divider 102 using a synchronous counter. A typical synchronous counter comprises a series of registers interspersed with logic. Typically, each logic stage of the synchronous counter outputs a signal at half the frequency of the signal input to it. If F_{OUT} is orders of magnitude smaller than F_{OSC}, many logic stages are required. This utilises a lot of power.

With increased market demand for lower power/longer battery life electronic devices, a lower power implementation of the frequency locked loop is needed. Additionally, there is a need to improve the accuracy and stability of the clock signal generated by the oscillator.

### SUMMARY OF THE INVENTION

According to a first aspect, there is provided a method of estimating an oscillator signal frequency, comprising: generating an oscillator signal having the oscillator signal frequency; clocking logic with the oscillator signal; at the logic, responding to a clock pulse by advancing-a state in a predetermined cycle of states; measuring the state of the logic at both bounds of a first time interval; determining an estimate of the oscillator signal frequency from a determined number of elapsed states of the logic in the first time interval; measuring the state of the logic at both bounds of a second time interval, the second time interval being longer than the first time interval; and determining a refined estimate of the oscillator signal frequency from a determined number of elapsed states of the logic in the second time interval.

Suitably, the method comprises determining the number of elapsed states of the logic in the second time interval by determining candidate numbers of elapsed states, each candidate number of elapsed states based on a different number of revolutions of the predetermined cycle of states during the second time interval.

Suitably, at least one candidate number of elapsed states is discarded based on the estimate of the oscillator signal frequency.

Suitably, the estimate of the oscillator signal frequency is a frequency range, and the method comprises discarding candidate numbers of elapsed states which would lead to the refined estimate not being encompassed within the frequency range.

Suitably, the estimate of the oscillator signal frequency is a frequency range, and the method comprises selecting a candidate number of elapsed states to be the determined number of elapsed states of the logic in the second time interval only if that candidate number of elapsed states would lead to the refined estimate being encompassed within the frequency range.

Suitably, the method further comprises: measuring the state of the logic at both bounds of a third time interval, the third time interval being longer than the second time interval; determining a further refined estimate of the oscillator signal frequency from a determined number of elapsed states of the logic in the third time interval.

Suitably, the method comprises determining the number of elapsed states of the logic in the third time interval by determining candidate numbers of elapsed states, each candidate number of elapsed states based on a different number of revolutions of the predetermined cycle of states during the third time interval.

Suitably, the refined estimate of the oscillator signal frequency is a refined frequency range, and the method comprises discarding candidate numbers of elapsed states which would lead to the further refined estimate not being encompassed within the refined frequency range.

Suitably, the refined estimate of the oscillator signal frequency is a refined frequency range, and the method comprises selecting a candidate number of elapsed states to be the determined number of elapsed states of the logic in the third time interval only if that candidate number would lead to the further refined estimate being encompassed within the refined frequency range.

Suitably, the logic comprises a first counter and a second counter, and the method comprises: clocking the first counter with the oscillator signal; at the first counter, producing a first counter output signal; and clocking the second counter with the first counter output signal; wherein the state of the logic is a combined state of the first counter and state of the second counter.

Suitably, the first counter output signal changes state at a fraction of the oscillator signal frequency such that the second counter is clocked at the fraction of the oscillator signal frequency.

Suitably the method comprises measuring the state of the logic by: measuring the state of the first counter; determining a time at which to measure the state of the second counter in dependence on the state of the first counter; and measuring the state of the second counter at the determined time.

Suitably, if the measured state of the first counter is indicative that the first counter output signal changed state in response to the most recent clock pulse received by the first counter, the method comprises selecting the determined time to be a predetermined interval after the measurement of the state of the first counter.

Suitably, the method further comprises predicting the number of elapsed states of the logic in the second time interval in dependence on the determined number of elapsed states of the logic in the first time interval.

Suitably, the method further comprises: comparing the determined number of elapsed states of the logic in the second time interval to the predicted number of elapsed states of the logic in the second time interval; and if the determined number of elapsed states of the logic in the second time interval and the predicted number of elapsed states of the logic in the second time interval are different, detecting an error in the determined number of elapsed states of the logic in the second time interval using a trellis network.

Suitably, the method further comprises: predicting the number of elapsed states of the logic in the third time interval in dependence on the determined number of elapsed states of the logic in the first time interval and on the determined number of elapsed states of the logic in the second time interval; comparing the determined number of elapsed states of the logic in the third time interval to the predicted number of elapsed states of the logic in the third time interval; and if the determined number of elapsed states of the logic in the third time interval and the predicted number of elapsed states of the logic in the third time interval are different, detecting an error in one or both of the determined number of elapsed states of the logic in the second time interval and the determined number of elapsed states of the logic in the third time interval using a trellis network.

According to a second aspect, there is provided a frequency locked loop for generating a clock signal, comprising: a controllable oscillator configured to, in dependence on a control signal, generate an oscillator signal having an oscillator signal frequency; a frequency divider coupled to the controllable oscillator configured to reduce the oscillator signal frequency to form a divided oscillator signal frequency; and a frequency detector coupled to the frequency divider and configured to generate the control signal in dependence on a reference signal frequency; wherein the frequency divider comprises a first counter and a second counter, the first counter configured to be clocked by the oscillator signal and to produce a first counter output signal, and the second counter configured to be clocked by the first counter output signal.

Suitably, the first counter is a twisted ring counter.

Suitably, the second counter is a linear feedback shift register.

Suitably, the frequency detector comprises: a first state register to the first counter; and a second state register to the second counter; the frequency detector being configured to determine the state of the frequency divider by measuring the state of the first counter at the first state register and measuring the state of the second counter at the second state register, and the frequency detector being configured to generate the control signal in dependence on the state of the frequency divider.

### BRIEF DESCRIPTION OF THE FIGURES

The present disclosure will now be described by way of example with reference to the accompanying drawings. In the drawings:

FIG. 1 illustrates a typical frequency locked loop;

FIG. 2 illustrates a frequency locked loop comprising two counters;

FIG. 3 illustrates an implementation of the frequency divider of FIG. 2 comprising a twisted ring counter and a linear feedback shift register;

FIG. 4 illustrates an implementation of the frequency detector of FIG. 2;

FIG. 5 is a flowchart illustrating a method of estimating the frequency of the oscillator signal;

FIG. 6 illustrates a binary chop method of implementing the flowchart of FIG. 5;

FIG. 7 illustrates a further binary chop method of implementing the flowchart of FIG. 5; and

FIG. 8 illustrates a trellis network.

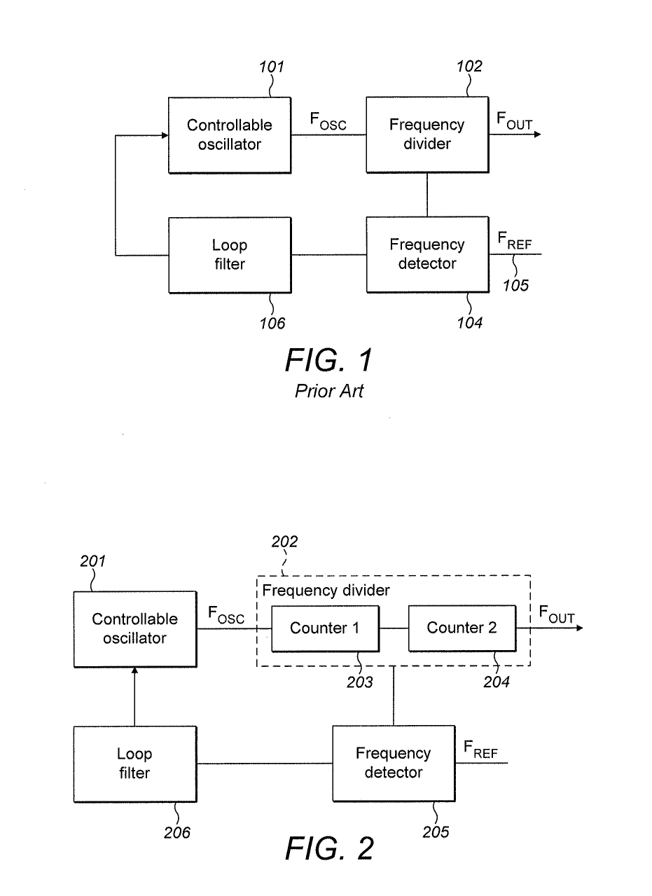

### DETAILED DESCRIPTION

The following description is presented by way of example to enable any person skilled in the art to make and use the invention. The invention is not limited to the examples described herein and various modifications to the disclosed examples will be readily apparent to those skilled in the art.

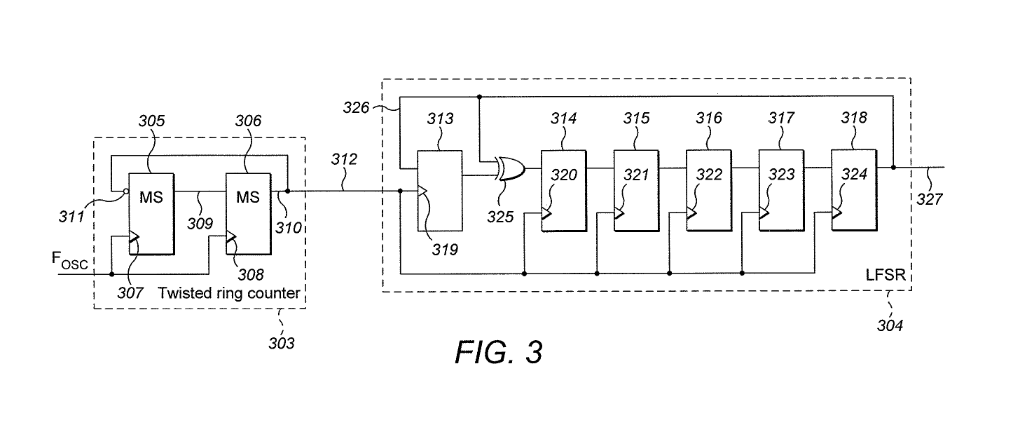

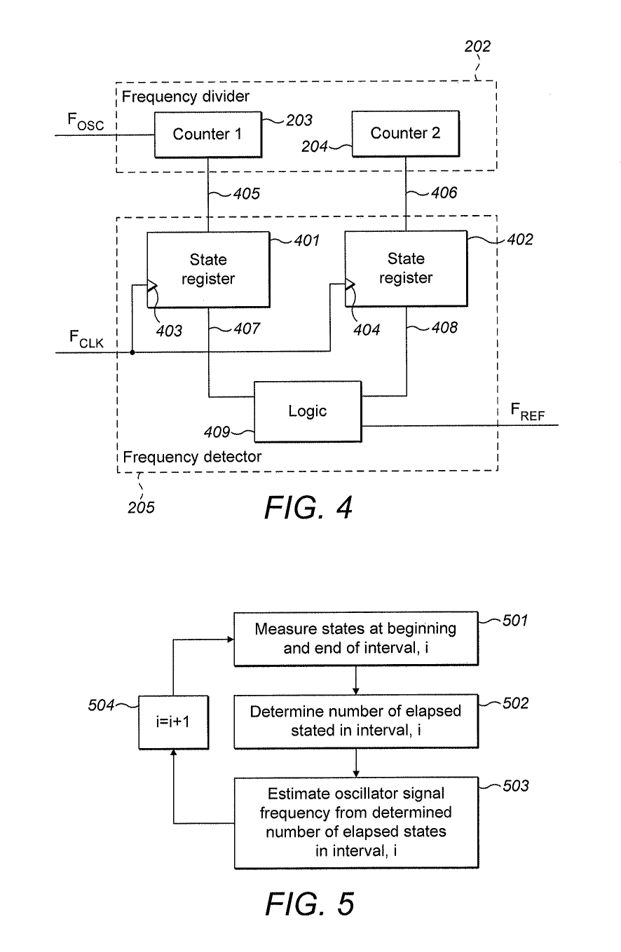

FIG. 2 is a schematic diagram of a frequency locked loop. FIG. 3 is a schematic diagram of an implementation of counter 1 and counter 2 of FIG. 2. FIG. 4 is a schematic diagram of an implementation of the frequency divider and frequency detector of FIG. 2. These figures present some components of the frequency locked loop in terms of functional blocks. Some functional blocks for carrying out functions well known in the art have in places been omitted from these figures. For example, functional blocks representing analogue to digital converters have been omitted from these figures.

FIG. 5 is a flowchart illustrating a method of estimating the frequency of an oscillator signal. This flowchart depicts an order in which the method of the flowchart can be performed. However, the flowchart is not intended to restrict the described method to being implemented in the order depicted. The steps of the method may be carried out in an alternative order to that depicted in the flowchart.

FIG. 2 is a schematic diagram illustrating the general arrangement of a frequency locked loop. Controllable oscillator 201 is connected to frequency divider 202. Frequency divider comprises counter 1 203 and counter 2 204. Counter 1 receives the output of controllable oscillator 201 as an input. Counter 2 receives the output of counter 1 as an input. The output of counter 2 is output from the frequency locked loop. Frequency detector 205 is connected to frequency divider 202. Frequency detector 205 receives as inputs an output from frequency divider 202 and a reference signal having frequency F_{REF}. Frequency detector 205 is connected to loop filter 206. Loop filter 206 receives as an input the output of frequency detector 205. The output of loop filter 206 is a control signal which controls controllable oscillator 201.

In operation, controllable oscillator 201 generates an oscillator signal having an oscillator signal frequency F_{OSC}. Frequency divider 202 transforms the oscillator signal to form a clock signal. Frequency divider 202 divides the oscillator signal frequency F_{OSC} down to a divided oscillator signal frequency F_{OUT}, such that the clock signal output by the frequency locked loop from the frequency divider 202 has a frequency F_{OUT}. Frequency divider 202 divides the oscillator signal frequency down in two stages: the first stage utilises counter 1 and the second stage utilises counter 2.

Counter 1 is clocked by the oscillator signal. Suitably, every time the oscillator signal changes state, the counter 1 changes state. In other words, each transition from 0 to 1 and 1 to 0 of the clock signal received from oscillator 201 causes the counter 1 to change state. So the counter 1 changes state with both the rising edge and the falling edge of the clock signal received from oscillator 201. The state of counter 1 advances in a predetermined manner. For example, counter 1 has a predetermined sequence of states which it advances through in a predetermined order. Suitably, counter 1 advances one state in the predetermined sequence of states on each clock edge of the clock signal received from oscillator 201. The predetermined sequence of states includes a limited number of distinct states. Suitably, once counter 1 has advanced through the distinct states, it returns to a state that it held previously and advances through the distinct states again. For example, if the predetermined sequence of states is n, n+1, n+2 . . . N−2, N−1, N then the N+1th state is n and the N+2th state is n+1. Similarly, the 2N+1th state is n and the 2N+2th state is n+1. Thus, counter 1 cycles around the predetermined sequence of states, each state transition occurring on receipt of a clock edge.

Counter 1 outputs a signal which changes state at a fraction of the rate at which counter 1 is clocked. In other words, counter 1's output signal has a frequency which is a fraction of the oscillator signal frequency F_{OSC}. Suitably, F_{OSC} is a multiple of the frequency of counter 1's output signal.

Counter 2 is clocked by counter 1's output signal. Thus, counter 2 is clocked at a fraction of the oscillator signal frequency F_{OSC}. Suitably, every time counter 1 cycles through its predetermined sequence of states once, counter 2 changes state once. In other words, counter 2 changes state either on receipt of a transition from 0 to 1 of the clock signal received from counter 1 or alternatively on receipt of a transition from 1 to 0 of the clock signal received from counter 1. So counter 2 changes state with one of the rising edge and the falling edge of the clock signal received from counter 1. The state of counter 2 advances in a predetermined manner. For example, counter 2 has a predetermined sequence of states which it advances through in a predetermined order. Suitably, counter 2 advances one state in the predetermined sequence of states during each clock period of the clock signal received from counter 1. The predetermined sequence of states includes a limited number of distinct states. Suitably, once counter 2 has advanced through the distinct states, it returns to a state that it held previously and advances through the distinct states again. For example, if the predetermined sequence of states is m, m+1, m+2 . . . M−2, M−1, M then the M+1th state is m and the M+2th state is m+1. Similarly, the 2M+1th state is m and the 2M+2th state is m+1. Thus, counter 2 cycles around the predetermined sequence of states, each state transition occurring on receipt of either the rising clock edge or the falling clock edge depending how counter 2 is configured.

Counter 2 outputs a signal which changes state at a fraction of the rate at which counter 2 is clocked. In other words, counter 2's output signal has a frequency which is a fraction of counter 1's output signal frequency. Suitably, F_{OSC} is a multiple of the frequency of counter 2's output signal.

Frequency detector 205 estimates the oscillator signal frequency F_{OSC}. Frequency detector 205 estimates F_{OSC} in dependence on a series of measured states of the frequency divider 202. The measured state of the frequency divider 202 is a combination of the measured state of counter 1 and the measured state of counter 2. A method of estimating the oscillator signal frequency F_{OSC} is described in more detail in relation to FIG. 5.

Frequency detector 205 also compares a frequency derived from F_{OSC} to a reference frequency F_{REF} and outputs a signal representative of the ratio of these two frequencies. Loop filter 206 filters the output of the frequency detector. The output of loop filter 206 is a control signal which is input to oscillator 201 to control the frequency F_{OSC} of the oscillator signal generated by the oscillator 201. Alternatively, the output of frequency detector 205 is the control signal which is input to oscillator 201 to control the frequency F_{OSC} of the oscillator signal generated by the oscillator 201.

FIG. 3 illustrates an exemplary implementation of frequency divider 202 of FIG. 2. Counter 1 303 is a twisted ring counter. Counter 2 304 is a linear feedback shift register (LFSR).

Twisted ring counter 303 comprises two master slave flip flops 305 and 306. Master slave flip flop 305 receives the differential F_{OSC} clock signal output from the oscillator 201 at clock input 307. Master slave flip flop 306 also receives the F_{OSC} clock signal output from the oscillator 201 at clock input 308. The output of master slave flip flop 305 on line 309 is input to master slave flip flop 306. The output of master slave flip flop 306 on line 310 is inverted at inverter 311 and then input to master slave flip flop 305. The output of master slave flip flop 306 is output from twisted ring counter 303 on line 312. Utilising two master slave flip flops in series as shown in FIG. 3 results in an output of the twisted ring counter 303 that changes state once for every four clock edges of the F_{OSC} clock signal. Thus, the frequency of the signal output from the twisted ring counter changes state at a quarter of the rate of the F_{OSC} clock signal. Thus, the frequency of the signal output from the twisted ring counter is ¼F_{OSC}. In other words, the twisted ring counter divides the frequency of the oscillator signal by a factor of four.

The signal output from the twisted ring counter clocks the LFSR 304. Thus, the LFSR 304 is clocked at a quarter of the rate at which the twisted ring counter is clocked.

The LFSR 304 comprises six flip flops 313, 314, 315, 316, 317 and 318. The flip flops are connected in series. Each flip flop receives the signal output from the twisted ring counter 312 as the clock signal at its clock input. Flip flop 313 receives the twisted ring counter output 312 at clock input 319. Flip flop 314 receives the twisted ring counter output 312 at clock input 320. Flip flop 315 receives the twisted ring counter output 312 at clock input 321. Flip flop 316 receives the twisted ring counter output 312 at clock input 322. Flip flop 317 receives the twisted ring counter output 312 at clock input 323. Flip flop 318 receives the twisted ring counter output 312 at clock input 324. The first flip flop in the series, flip flop 313, receives as its data input on line 326 the output of the LFSR which is the output of the last flip flop in the series, flip flop 318. The output of flip flop 313 is input to an exclusive-or gate 325 (XOR). The other input to the XOR gate is the output of the LFSR which is the output of the last flip flop in the series, flip flop 318. The output of the XOR gate is the input to the next flip flop in the series, flip flop 314. The output of flip flop 314 is the input to the next flip flop in the series, flip flop 315. The output of flip flop 315 is the input of the next flip flop in the series, flip flop 316. The output of flip flop 316 is the input of the next flip flop in the series, flip flop 317. The output of flip flop 317 is the input of the last flip flop in the series, flip flop 318. The output of flip flop 318 is the output of the LFSR. The XOR gate outputs a 0 if its two inputs are the same, and outputs a 1 if its two inputs are different.

FIG. 3 as described above illustrates one configuration of the twisted ring counter and one configuration of the LFSR. However, it will be understood that other configurations of the twisted ring counter and LFSR are possible. For example, the twisted ring counter may comprise further master slave flip flops in order to reduce the frequency of the oscillator signal further. As a further example, the LFSR may comprise further flip flops in order to increase the number of states in the predetermined sequence of states of the LFSR, and hence the time taken for the predetermined state sequence to repeat.

The use of a twisted ring counter and an LFSR as the two counters of frequency divider 202 of FIG. 2 is one exemplary implementation. In another example, counter 1 of FIG. 2 is a twisted ring counter and counter 2 of FIG. 2 is a ripple counter.

Utilising two counters to implement the frequency divider 202, one of which is a twisted ring counter saves power relative to known implementations which use a single synchronous counter. Synchronous counters incorporate logic between each flip flop. This logic consumes a relatively large amount of power. The twisted ring counter reduces the frequency of the oscillator signal by a factor of four without using any logic except for the inverter 311. Thus, the twisted ring counter uses less power than a synchronous counter. Additionally, the subsequent LFSR performs the remainder of the frequency reduction by operating at a quarter of the speed it would have had to operate at if it had directly received the oscillator signal as a dock input. Thus, the LFSR requires a quarter of the power it would have needed if it had directly received the oscillator signal as a clock input. Additionally, logic stages in between the flip flops of the LFSR are minimized in order to reduce the LFSR's power consumption. Thus, this two counter solution saves power.

Each master slave flip flop of the twisted ring counter 303 comprises two latches in series (master and slave). Each of the master latches changes state with one clock edge of the received oscillator signal. The slave latches change state with the other clock edge of the received oscillator signal. The state of the twisted ring counter 303 is the combination of states of its four constituent latches. The state of each latch of the twisted ring counter 303 is dependent on the states of the other latches of the twisted ring counter 303. The manner in which the state of each latch advances is deterministic. Thus, the state of the twisted ring counter as a whole advances in a predetermined manner. The twisted ring counter 303 shown in FIG. 3 has a sequence of eight distinct states that it cycles through. Once it has progressed through these eight states in turn, it cycles through the eight states again in the same order. In other words, the ninth state is the same as the first state. The seventeenth state is the same as the first state.

Each flip flop of the LFSR 304 changes state with each clock edge of the signal output from the twisted ring counter 303. The state of the LFSR is the combination of states of its six constituent flip flops. The state of each flip flop of the LFSR is dependent on the states of the other flip flops of the LFSR. The manner in which the state of each flip flop advances is deterministic. Thus, the state of the LFSR as a whole advances in a predetermined manner. The LFSR shown in FIG. 3 has a sequence of 63 distinct states that it cycles through. Once it has progressed through these 63 states in turn, it cycles through the 63 states again in the same order. In other words, the 64^{th} state is the same as the first state. The 127^{th} state is the same as the first state. The LFSR state in which each flip flop is in the same logic state 0 is an illegal state which is not included in the 63 distinct states mentioned above. Additional logic is incorporated into the LFSR shown in FIG. 3 in order to avoid this state from being entered by the LFSR.

The state of the frequency divider 202 is a combination of the states of the twisted ring counter 303 and the LFSR 304. Thus, the frequency divider 202 has 8×63=504 states. The state of the frequency divider as a whole changes on every clock edge of the oscillator signal. Thus, the state of the frequency divider as a whole changes every half clock cycle that it is clocked at by the oscillator signal. The manner in which the state of the frequency divider advances is deterministic. The state of the frequency divider progresses in a predetermined manner through a sequence of 504 states. Once it has progressed through these 504 states in turn, it cycles through the 504 states again in the same order.

FIG. 4 illustrates an exemplary implementation of frequency detector 205 of FIG. 2. Frequency detector 205 comprises two state registers 401, 402. State register 401 receives the state of counter 1 as an input on line 405. State register 402 receives the state of counter 2 as an input on line 406. State register 401 is clocked by a clock signal F_{CLK} which is input to clock input 403. State register 402 is clocked by the same clock signal F_{CLK} which is input to clock input 404. Suitably, the clock signal has a very stable frequency. For example, the clock signal may be derived from a crystal oscillator. State register 401 outputs the state of counter 1 on line 407 to logic 409. State register 402 outputs the state of counter 2 on line 408 to logic 409. Logic 409 uses the measured state of counter 1 and the measured state of counter 2 to determine the state of the frequency divider. Logic 409 uses the state of the frequency divider to determine accurately the frequency of the oscillator signal F_{OSC}. Logic 409 then compares the frequency of the oscillator signal F_{OSC} to a reference signal frequency F_{REF} and generates a control signal in dependence on this comparison to control the oscillator.

Suitably, logic 409 utilizes the measured state of the frequency divider and the known sequence of states through which the frequency divider cycles in order to estimate the frequency of the oscillator signal F_{OSC}. FIG. 5 is a flowchart illustrating the method steps taken by logic 409 in order to estimate the frequency of the oscillator signal F_{OSC}.

At step 501 the frequency detector measures the state of the frequency divider at the beginning and end of a first time interval. For example, this time interval may be 1 μs. Suitably, the frequency detector measures the state of the frequency divider using the state registers described with reference to FIG. 4.

At step 502, the frequency detector determines the number of elapsed states in the first time interval. As an example, consider the case in which the frequency divider is in state 3 of 504 at the beginning of the first time interval and in state 245 of 504 at the end of the first time interval. Because the frequency divider cycles through the 504 states, it is not known from this information alone how many elapsed states there have been in the first time interval. It might be that the state of the frequency divider has progressed from state 3 to 245 in one cycle and thus 242 states have elapsed. However, it might be that the state of the frequency divider has progressed from state 3 through to 504 in one cycle and then from state 1 to 245 in the next cycle, in which case 746 states have elapsed. Similarly, the frequency divider may have advanced through two, three or more cycles of the predetermined sequence of states. Suitably, the frequency of the oscillator signal is known to a certain accuracy. For example, the frequency of the oscillator signal might be known to be AHz±BHz. Since the state changes every half clock period, the number of elapsed states is inversely proportional to the frequency of the oscillator signal. Thus, the number of elapsed states in the first time interval is known to be C states±D states from the oscillator signal frequency AHz±BHz. Suitably, the length of the first time interval is selected such that the uncertainty D in the number of states that has elapsed is less than the total number of states in the predetermined sequence of states. Thus, in this way it is known which cycle of the 504 states the 245 state measurement is in. Thus, the number of elapsed states in the first interval is determined from the measured state at the beginning of the first time interval, the measured state at the end of the first time interval, and the known value and accuracy of the oscillator signal frequency.

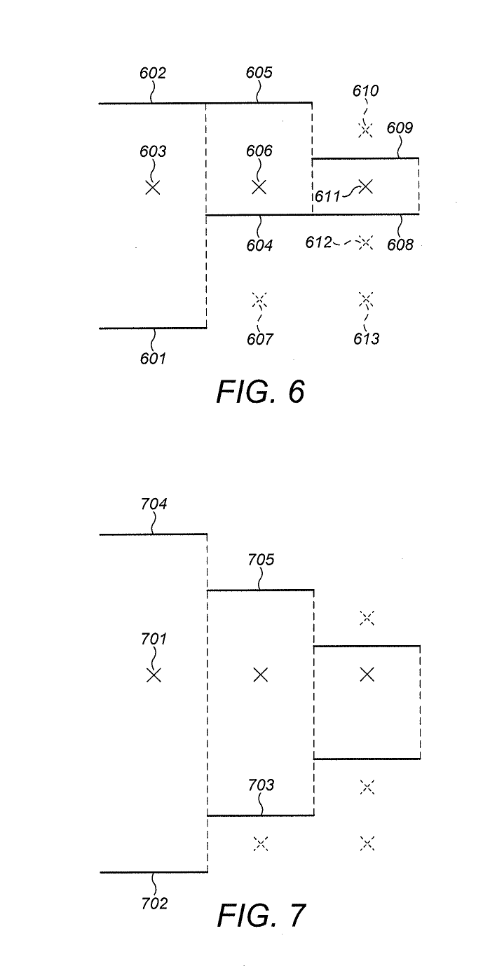

FIG. 6 illustrates the uncertainty in the frequency of the oscillator signal F_{OSC}. The base line 601 represents the minimum frequency of the oscillator signal, AHz−BHz. The top line 602 represents the maximum frequency of the oscillator signal, AHz+BHz. The range between the base line 601 and the top line 602 also represents the range of frequency divider states which could be measured at the end of the first time interval given the state measurement at the beginning of the first time interval and the known accuracy of the oscillator signal frequency.

Suitably, the length of the first time interval is chosen such that only one cycle of the predetermined sequence of states is represented between the base line 601 and the top line 602.

At step 503, the oscillator signal frequency is estimated from the determined number of elapsed states of the frequency divider in the first time interval. Since the frequency divider changes state with every half clock cycle of the oscillator signal, the number of periods of the clock cycle in the first time interval is half the number of elapsed states. Thus, an estimate of the frequency of the oscillator is given by:

$${F}_{{OSC}_{i}} = \frac{2 i}{{s}_{i}} \qquad ( equation 1 )$$

where F_{OSCi} is the estimate of the frequency of the oscillator signal in Hz, i is the length of the time interval in seconds and sᵢ is the number of elapsed states during the time interval.

The cross marked 603 on FIG. 6 is the estimate of the frequency of the oscillator determined from equation 1 from the first time interval. The accuracy of this estimate of the oscillator signal frequency F_{OSC} is limited. Since the frequency divider only changes state every half clock cycle, the accuracy of the number of elapsed states over the first time interval is only accurate to half a clock cycle. Thus, the frequency of the oscillator signal is now A′Hz±B′Hz where B′ is smaller than B.

At step 504 of FIG. 5, the method advances to the next time interval. The method steps 501, 502 and 503 of FIG. 5 then repeat for the next time interval. So, at step 501 the frequency detector measures the state of the frequency divider at the beginning and end of a second time interval. The second time interval is longer than the first time interval. For example, this second time interval may be 2 μs. In one example implementation, the first time interval and the second time interval begin at the same time. In other words, the beginning state measurement of the first and second time intervals are the same. This reduces the total number of state measurements taken by the frequency detector, and thus saves power. Also, this reduces the time taken to take all the state measurements, thus enables the oscillator signal frequency to be estimated more quickly. Suitably, the frequency detector measures the state of the frequency divider using the state registers described with reference to FIG. 4.

At step 502, the frequency detector determines the number of elapsed states in the second time interval. As described above with reference to the first time interval, it is not known from the beginning and end states of the second time interval alone how many elapsed states there have been in the second time interval. However, the oscillator frequency is now known to an accuracy of ±B′Hz which is more accurately than it was known before the first time interval. In the same manner as described above with respect to the first time interval, the number of elapsed states in the second time interval is determined from the measured state at the beginning of the second time interval, the measured state at the end of the second time interval, and the known value and accuracy of the estimate of the oscillator signal frequency determined from the first time interval measurements.

FIG. 6 illustrates one method of determining which cycle of the predetermined sequence of states the second state measurement for the second time interval has come from. This method is a binary chop method. The first estimate of the oscillator signal frequency 603 determined during the first iteration of the method of FIG. 5 is in the top half of the frequency range that it could have been in (according to the known accuracy of the oscillator signal frequency prior to the measurements of the first time interval). For the second iteration of the method of FIG. 5, the frequency range is reduced by half. Since the first estimate of the oscillator signal frequency is in the top half of the frequency range, the top half of the frequency range is used for the second iteration of the method. Thus, the base line 604 for the second iteration has been moved to half way up the frequency range of the first iteration. The frequency range from the base line 604 to the top line 605 encompasses the estimated frequency of the oscillator signal frequency determined during the first iteration and its associated error of ±B′Hz.

Candidates for the number of elapsed states in the second time interval are generated, each candidate based on a different number of revolutions of the predetermined sequence of states during the second time interval. Two of these candidates are illustrated by points 606 and 607 on FIG. 6. Candidate 607 lies inside the frequency range of the first iteration of the method of FIG. 5, but outside the frequency range of the second iteration of the method of FIG. 5. Thus, candidate 607 is discarded. This is because the oscillator signal frequency that it corresponds to is not within the frequency range encompassed by base line 604 and top line 605. The oscillator signal frequency range that it corresponds to is not within the estimated oscillator signal frequency determined during the first iteration of the method of FIG. 5. Candidate 606 lies inside the frequency range of both the first and second iterations of the method of FIG. 5. Candidate 606 corresponds to an oscillator signal frequency that is encompassed by base line 604 and top line 605. Candidate 606 corresponds to an oscillator signal frequency that is encompassed within the estimated oscillator signal frequency determined during the first iteration of the method of FIG. 5. Thus, candidate 606 is determined to be the number of elapsed states in the second time interval.

At step 503, a refined estimate of the oscillator signal frequency is determined from the determined number of elapsed states of the frequency divider in the second time interval using equation 1. The cross marked 606 on FIG. 6 corresponds to the refined estimate of the frequency of the oscillator determined from equation 1 for the second time interval. The accuracy of this refined estimate of the oscillator signal frequency F_{OSC} is greater than the accuracy of the estimate generated during the first iteration of the method of FIG. 5. Since the frequency divider only changes state every half clock cycle, the accuracy of the number of elapsed states over the second time interval is only accurate to half a clock cycle. Thus, the frequency of the oscillator signal is now A″Hz±B″Hz where B″ is smaller than B′.

At step 504 of FIG. 5, the method advances to the next time interval.

The iteration of FIG. 5 using a third time interval proceeds as described with respect to the second time interval. The third time interval is longer than the second time interval. For example, the third time interval may be 4 μs. In one implementation, the first, second and third time intervals all begin at the same time. The refined estimate of the oscillator signal frequency 606 determined during the second iteration of the method of FIG. 5 is in the bottom half of the frequency range bounded by base line 604 and top line 605. For the third iteration of the method of FIG. 5, the frequency range is reduced by half again. Since the refined estimate of the oscillator signal frequency is in the bottom half of the frequency range, the bottom half of the frequency range is used for the third iteration of the method. Thus, the top line 609 has been moved half way down the frequency range of the second iteration. The frequency range from the base line 608 to the top line 609 encompasses the estimated frequency of the oscillator signal frequency determined during the second iteration and its associated error of ±B″Hz.

The candidates for the number of elapsed states in the third time interval are illustrated by points 610, 611, 612 and 613 on FIG. 6. Candidates 610, 612 and 613 are discarded because they are outside the frequency range of the third iteration of the method of FIG. 5. Candidate 611 lies inside the frequency range of the third iteration of the method of FIG. 5. Candidate 611 corresponds to an oscillator signal frequency that is encompassed within the refined estimate of the oscillator signal frequency determined during the second iteration of the method of FIG. 5. Thus, candidate 611 is determined to be the number of elapsed states in the third time interval.

At step 503, a further refined estimate of the oscillator signal frequency is determined from the determined number of elapsed states of the frequency divider in the third time interval using equation 1.

For each subsequent iteration of the method of FIG. 5, the time interval is longer than the time interval of the last iteration. The more iterations of the method of FIG. 5 that are completed, the more accurately the oscillator signal frequency is determined.

The binary chop method of FIG. 6 is one way to implement the method of FIG. 5. However, a single bit error in a state measurement could cause a large error in the determined oscillator signal frequency. If the determined number of elapsed states is in the middle of the range, then a one bit error could cause the wrong half of the range to be discarded for the next iteration. FIG. 7 illustrates another binary chop implementation. In this implementation, if the determined number of elapsed states is in the middle of the range, as illustrated by point 701, then the range is chopped by half such that the base line 702 is moved a quarter of the range up to base line 703. Similarly, the top line 704 is moved a quarter of the range down to top line 705.

Suitably, a combination of the binary chop methods illustrated in FIGS. 6 and 7 is used. For example, the binary chop method of FIG. 6 is used by default, but if the determined number of elapsed states for that iteration is around the middle of the frequency range, the binary chop method of FIG. 7 is used for that iteration instead.

The use of two counters to implement the frequency divider 202 of the frequency locked loop is a lower power solution as described above. The state of counter 2 only advances when the output of counter 1 changes state. The output of counter 1 changes state more slowly than the rate at which it is clocked. In the twisted ring counter and LFSR counter example above, the twisted ring counter's output changes at a quarter of the rate it is clocked. However, because counter 2 is clocked by the output of counter 1, the state of counter 1 will update before the state of counter 2 in those clock cycles where the output of counter 1 changes state. In other words, counter 1 and counter 2 are clocked asynchronously. This can cause a race hazard. If the states of both counter 1 and counter 2 are sampled at the same time just after counter 1 has changed the state of its output signal, then it is possible that those states may be sampled after counter 1 has updated its state but before counter 2 has updated its state. This would result in a measurement error of ±8 states in the determined number of elapsed states in the time interval. A −8 error occurs if the state measurement at the beginning of the time interval has been affected by a race hazard, but the state measurement at the end of the time interval is correct. A +8 error occurs if the state measurement at the beginning of the time interval is correct, but the state measurement at the end of the time interval has been affected by a race hazard.

Suitably, this situation is avoided by controlling when to sample the state of counter 2 in dependence on the measured state of counter 1. If counter 1 is measured to be in the state that corresponds to it having just changed the state of its output signal on the most recently received clock edge, then a time t is allowed to lapse before measuring the state of counter 2. The time t is set to be sufficiently long for counter 2 to have updated its state after receiving the clock edge from counter 1. If, on the other hand, counter 1 is measured to be in a state that corresponds to it having not changed the state of its output signal for at least half a clock cycle, then the state of counter 2 may be immediately sampled.

Suitably, the frequency detector implements a trellis network in order to detect and correct errors in the determined oscillator signal frequency. Suitably, the state of the frequency divider is measured at times 0, T, 2T, 4T, 8T etc. The first time interval is bounded by 0 and T. The second time interval is bounded by 0 and 2T. The third time interval is bounded by 0 and 4T. And so on. For example, the state of the frequency divider is measured at times 0, 1 μs, 2 μs, 4 μs, 8 μs etc. Thus, the number of elapsed states of the frequency divider in each time interval should be double the number of elapsed states in the previous time interval, and four times the number of elapsed states in the time interval prior to that.

sᵢ=2[sᵢ₋₁modp] (equation 2)

sᵢ=4[sᵢ₋₂modp] (equation 3)

where sᵢ is the number of elapsed states in interval i, and p is the total number of states in the predetermined sequence of states.

Thus, following determination of the number of elapsed states in the first time interval, a predicted number of elapsed states in the second time interval is made using equation 2. Similarly, a predicted number of elapsed states in the third time interval is made using equation 3. Following determination of the number of elapsed states in the second time interval, a further prediction of the number of elapsed states in the third time interval is made using equation 2. And so on.

Once the counter state measurements are made for the second time interval and the number of elapsed states in the second time interval determined, this is compared to the predicted number of elapsed states in the second time interval. If the predicted number of elapsed states in the second time interval is different to the determined number of elapsed states in the second time interval, then this is indicative of an error in the state measurements. Similarly, once the counter state measurements are made for the third time interval and the number of elapsed states in the third time interval determined, this is compared to the predicted number of elapsed states in the third time interval. If the predicted number of elapsed states in the third time interval is different to the determined number of elapsed states in the third time interval, then this is indicative of an error in the state measurements.

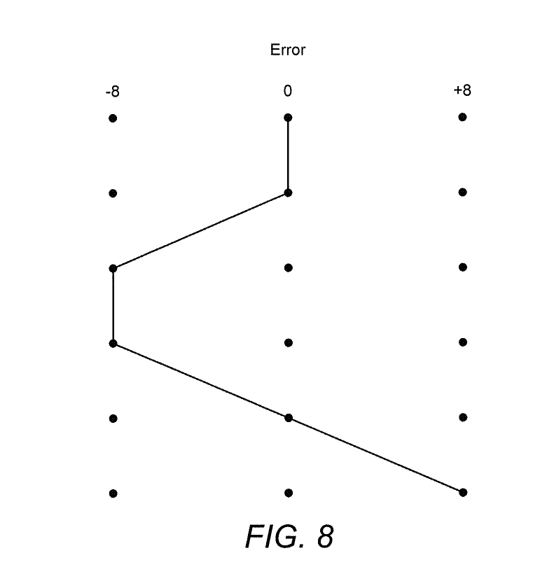

The likely errors of the measurements are bit errors of ±1 states and race hazards. The race hazards cause errors of plus or minus the number of states in counter 1. For the twisted ring counter discussed above, a race hazard causes an error of ±8. A trellis network is created which includes the likely errors. FIG. 8 illustrates a trellis network. Each row corresponds to an iteration of the method of FIG. 5. 0 is the predicted number of elapsed states in the interval. Race hazard errors of −8 and +8 are illustrated. When an error is indicated by a determined number of elapsed states in an interval being different to a predicted number of elapsed states in that interval, the trellis network is used to work back from the determined number of elapsed states in that interval in order to work out which state measurement was in error. The trellis network uses the determined and predicted numbers of elapsed states at each interval to detect the inconsistent state measurement. There may be more than one error. In the illustration of FIG. 8, three 8 bit errors are shown. An error of −8 occurs in the third iteration of the method of FIG. 5. An error of +8 occurs in the fifth iteration of the method of FIG. 5. An error of +8 occurs in the sixth iteration of the method of FIG. 5. Once the error or errors are detected, the state measurements containing those errors are corrected, and the resulting estimates of the oscillator signal frequency also corrected. The trellis network method is thus used to detect and correct race hazard errors. A trellis network can also be used in a similar manner to detect and correct 1 bit errors.

A −8 error occurs if the state measurement at the beginning of the time interval has been affected by a race hazard, but the state measurement at the end of the time interval is correct. Thus, on detecting a −8 error, the state measurement at the beginning of the time interval is corrected by moving it on 8 states in the predetermined state sequence. A+8 error occurs if the state measurement at the beginning of the time interval is correct, but the state measurement at the end of the time interval has been affected by a race hazard. Thus, on detecting a+8 error, the state measurement at the end of the time interval is corrected by moving it backwards 8 states in the predetermined state sequence.

The frequency locked loop described herein may be used to implement a local oscillator that drives a frequency mixer of a transmit chain of a transmitter. If the transmitter is operating according to a protocol in which the transmitted signal is modulated, this modulation may be implemented by modulating the frequency of the local oscillator. Thus causes the frequency at which counter 1 is clocked to vary in accordance with the modulation, and hence causes errors in the states measured by the frequency detector. However, the transmission modulation scheme is known, thus the effect that the modulation scheme has on the clocking of counter 1 is determined. Thus, the consequential error on the measured states is determined. Using this information, the errors are detected and corrected by the trellis network. Thus, the frequency locked loop is able to continue to correct for drift of the frequency of the oscillator signal even whilst the transmitter is transmitting and hence modulating the oscillator signal frequency.

The frequency estimation method described with respect to FIG. 5 is not restricted to estimating the frequency of a signal via the states of a frequency divider. The frequency estimation method described applies to estimating the frequency of any signal which is used to clock logic which changes state in a deterministic manner when clocked. That logic may consist of a single counter. Examples of that single counter are a synchronous counter or an LFSR or a ripple counter. Alternatively, that logic may consist of two counters in series, the second counter being clocked by the output of the first counter. The two counters may be a twisted ring counter and an LFSR, or a twisted ring counter and a ripple counter.

In one example, the frequency estimation method described herein is used to overcome the disturbance caused to a local oscillator in a transceiver. Suitably, the local oscillator provides a local oscillator signal which drives a frequency mixer in the transmit chain and which also drives a frequency mixer in the receive chain of a transceiver. When a signal is being transmitted, the local oscillator is disturbed by the power amplifier of the transmit chain. This causes the frequency of the signal output by the local oscillator to be pulled. This is a particular problem in low power chips which use low power local oscillators which are easily disturbed. It is also increasingly a problem as chips are made smaller which results in the local oscillator being located closer to the power amplifier.

The frequency estimation method described herein is used to measure the frequency of the local oscillator signal when the chip is not transmitting. The frequency estimation method described herein is used again to measure the frequency of the local oscillator signal when the chip is transmitting and hence the power amplifier is operational and pulling the local oscillator. The difference in the local oscillator frequency before and during the transmission is determined. Then, during transmission, a frequency locked loop is used to adjust the frequency of the local oscillator by the determined difference to cancel the pulling caused by the power amplifier.

This is applicable to a chip which is operating according to a radio standard which utilises a frequency modulated system, for example an FSK or PSK protocol. As an example, this method is applicable to a Bluetooth Low Energy protocol.

Suitably, the described controllable oscillator is a current controlled oscillator. Alternatively, the described controllable oscillator is a voltage controlled oscillator.

Suitably, the frequency divider is implemented digitally. Suitably, the frequency detector is implemented digitally. Suitably, the loop filter is implemented digitally.

The described frequency locked loop circuitry is suitably incorporated within a computing-based device. The computing-based device may be an electronic device. Suitably, the computing-based device comprises one or more processors for processing computer executable instructions to control operation of logic 409 of the frequency detector 205 to control implementation of the methods described herein. The computer executable instructions can be provided using any computer-readable media such as a memory. Further software can be provided at the computing-based device to implement the methods described herein. The methods described herein may be performed by software in machine readable form on a tangible storage medium.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A method of estimating an oscillator signal frequency, comprising:
generating an oscillator signal having the oscillator signal frequency;
clocking logic with the oscillator signal;
at the logic, responding to a clock pulse by advancing a state in a predetermined cycle of states;
measuring the state of the logic at both bounds of a first time interval;
determining an estimate of the oscillator signal frequency from a determined number of elapsed states of the logic in the first time interval;
measuring the state of the logic at both bounds of a second time interval, the second time interval being longer than the first time interval; and
determining a refined estimate of the oscillator signal frequency from a determined number of elapsed states of the logic in the second time interval.

2. A method as claimed in claim 1, comprising determining the number of elapsed states of the logic in the second time interval by determining candidate numbers of elapsed states, each candidate number of elapsed states based on a different number of revolutions of the predetermined cycle of states during the second time interval.

3. A method as claimed in claim 2, further comprising discarding at least one candidate number of elapsed states based on the estimate of the oscillator signal frequency.

4. A method as claimed in claim 3, wherein the estimate of the oscillator signal frequency is a frequency range, and wherein the method comprises discarding candidate numbers of elapsed states which would lead to the refined estimate not being encompassed within the frequency range.

5. A method as claimed in claim 2, wherein the estimate of the oscillator signal frequency is a frequency range, and wherein the method comprises selecting a candidate number of elapsed states to be the determined number of elapsed states of the logic in the second time interval only if that candidate number of elapsed states would lead to the refined estimate being encompassed within the frequency range.

6. A method as claimed in claim 1, further comprising:
measuring the state of the logic at both bounds of a third time interval, the third time interval being longer than the second time interval;
determining a further refined estimate of the oscillator signal frequency from a determined number of elapsed states of the logic in the third time interval.

7. A method as claimed in claim 6, comprising determining the number of elapsed states of the logic in the third time interval by determining candidate numbers of elapsed states, each candidate number of elapsed states based on a different number of revolutions of the predetermined cycle of states during the third time interval.

8. A method as claimed in claim 7, wherein the refined estimate of the oscillator signal frequency is a refined frequency range, and wherein the method comprises discarding candidate numbers of elapsed states which would lead to the further refined estimate not being encompassed within the refined frequency range.

9. A method as claimed in claim 7, wherein the refined estimate of the oscillator signal frequency is a refined frequency range, and wherein the method comprises selecting a candidate number of elapsed states to be the determined number of elapsed states of the logic in the third time interval only if that candidate number would lead to the further refined estimate being encompassed within the refined frequency range.

10. A method as claimed in claim 1, wherein the logic comprises a first counter and a second counter, the method comprising:
clocking the first counter with the oscillator signal;
at the first counter, producing a first counter output signal; and
clocking the second counter with the first counter output signal;
wherein the state of the logic is a combined state of the first counter and state of the second counter.

11. A method as claimed in claim 10, wherein the first counter output signal changes state at a fraction of the oscillator signal frequency such that the second counter is clocked at the fraction of the oscillator signal frequency.

12. A method as claimed in claim 11, comprising measuring the state of the logic by:
measuring the state of the first counter;
determining a time at which to measure the state of the second counter in dependence on the state of the first counter; and
measuring the state of the second counter at the determined time.

13. A method as claimed in claim 12, wherein if the measured state of the first counter is indicative that the first counter output signal changed state in response to the most recent clock pulse received by the first counter, selecting the determined time to be a predetermined interval after the measurement of the state of the first counter.

14. A method as claimed in claim 1, further comprising predicting the number of elapsed states of the logic in the second time interval in dependence on the determined number of elapsed states of the logic in the first time interval.

15. A method as claimed in claim 14, further comprising:
comparing the determined number of elapsed states of the logic in the second time interval to the predicted number of elapsed states of the logic in the second time interval; and
if the determined number of elapsed states of the logic in the second time interval and the predicted number of elapsed states of the logic in the second time interval are different, detecting an error in the determined number of elapsed states of the logic in the second time interval using a trellis network.

16. A method as claimed in claim 6, further comprising:
predicting the number of elapsed states of the logic in the third time interval in dependence on the determined number of elapsed states of the logic in the first time interval and on the determined number of elapsed states of the logic in the second time interval;
comparing the determined number of elapsed states of the logic in the third time interval to the predicted number of elapsed states of the logic in the third time interval; and
if the determined number of elapsed states of the logic in the third time interval and the predicted number of elapsed states of the logic in the third time interval are different, detecting an error in one or both of the determined number of elapsed states of the logic in the second time interval and the determined number of elapsed states of the logic in the third time interval using a trellis network.

17. A frequency locked loop for generating a clock signal, comprising:
a controllable oscillator configured to, in dependence on a control signal, generate an oscillator signal having an oscillator signal frequency;
a frequency divider coupled to the controllable oscillator configured to reduce the oscillator signal frequency to form a divided oscillator signal frequency; and
a frequency detector coupled to the frequency divider and configured to generate the control signal in dependence on a reference signal frequency;
wherein the frequency divider comprises a first counter and a second counter, the first counter configured to be clocked by the oscillator signal and to produce a first counter output signal, and the second counter configured to be clocked by the first counter output signal.

18. A frequency locked loop as claimed in claim 17, wherein the first counter is a twisted ring counter.

19. A frequency locked loop as claimed in claim 17, wherein the second counter is a linear feedback shift register.

20. A frequency locked loop as claimed in claim 17, wherein the frequency detector comprises:
a first state register to the first counter; and
a second state register to the second counter;
the frequency detector being configured to determine the state of the frequency divider by measuring the state of the first counter at the first state register and measuring the state of the second counter at the second state register, and the frequency detector being configured to generate the control signal in dependence on the state of the frequency divider.
